(19) United States
(12) Patent Application Publication
(10) Pub. No.: US 2008/0017968 A1
(43) Pub. Date: Jan. 24, 2008

(54) Stack type semiconductor package and method of fabricating the same

(75) Inventors: Young-shin Choi, Cheonan-si (KR); Young-lyong Kim, Seongnam-si (KR); Kun-dae Yeom, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/812,580

(22) Filed: Jun. 20, 2007

(30) Foreign Application Priority Data
Jul. 18, 2006 (KR) 10-2006-0067099

(51) Int. Cl. H01L 23/02; H01L 21/00

(52) U.S. Cl. 257/686; 438/109; 257/E23.18; 257/E21.001

(57) ABSTRACT

A stack type semiconductor package, and a method of fabricating the same are provided. The stack type semiconductor package may include a lower unit package and an upper unit package. The lower unit package may include a substrate, and a semiconductor chip on an upper surface of the substrate. A bump may be on an upper surface of the substrate, and a protecting layer, covering the semiconductor chip, may be formed. The protecting layer may include a via hole partially exposing the bump. The upper unit package may be on the protecting layer, and may include an internal connection solder ball on a lower surface of the upper unit package. The internal connection solder ball may be inserted into the via hole and connected to the bump.

### PRIORITY STATEMENT

This application claims priority under 35 U.S.C. §119 to Korean Patent Application No. 10-2006-0067099, filed on Jul. 18, 2006, in the Korean Intellectual Property Office (KIPO), the entire contents of which are incorporated herein by reference.

### BACKGROUND

1. Field

Example embodiments relate to a semiconductor package and method of fabricating the same. Other example embodiments relate to a stack type semiconductor package composed of a plurality of stacked unit packages and method of fabricating the same.

2. Description of the Related Art

As semiconductor products become smaller, semiconductor packages may be required to be lighter, thinner and smaller in line with higher integration of a semiconductor chip itself. Accordingly, a stack type semiconductor package composed of a plurality of stacked packages has been developed.

In the stack type semiconductor package, stacked single unit packages may be reliably and electrically connected to one another. One example of the stack type semiconductor package may be a stack type package structured such that a ball grid array (BGA) package may be on a lower portion of the stack type package, and another BGA package may be stacked on the lower BGA package. In the stack type package, a solder ball of the upper BGA package may be mounted on a ball land of the lower BGA package to be electrically connected to the ball land. However, when physical impact is applied to the stack type semiconductor package, connection between the solder ball and the ball land may be broken.

### SUMMARY

Example embodiments provide a stack type semiconductor package for realizing reliable electrical connections between stacked single unit packages, and a method of fabricating the same.

According to example embodiments, there is provided a stack type semiconductor package. The stack type semiconductor package may include a lower unit package and an upper unit package. The lower unit package may include a substrate, and a semiconductor chip on an upper surface of the substrate. A bump may be on an upper surface of the substrate, and a protecting layer, covering the semiconductor chip, may be formed. The protecting layer may include a via hole partially exposing the bump. The upper unit package may be on the protecting layer, and may have an internal connection solder ball on a lower surface of the upper unit package. The internal connection solder ball may be inserted into the via hole and connected to the bump.

According to example embodiments, there is provided a method of fabricating a stack type semiconductor package. In the method, a lower semiconductor package may be formed. Forming the lower semiconductor package may include forming a bump on an upper surface of a substrate. A semiconductor chip may be provided on the upper surface of the substrate. A protecting layer, covering the semiconductor chip on the substrate, and having a via hole partially exposing the bump, may be formed. An upper semiconductor package may be provided on the protecting layer. Providing the upper semiconductor package may include inserting an internal connection solder ball on a lower surface of the upper semiconductor package, and into the via hole and connected to the bump.

### BRIEF DESCRIPTION OF THE DRAWINGS

Example embodiments will be more clearly understood from the following detailed description taken in conjunction with the accompanying drawings. FIGS. 1A-6 represent non-limiting, example embodiments as described herein.

FIGS. 1A-1D are cross-sectional views illustrating a method of fabricating a stack type semiconductor package according to example embodiments;

FIG. 2 is a cross-sectional view illustrating a method of fabricating a single unit package according to example embodiments; and

FIGS. 3-6 are cross-sectional views illustrating stack type semiconductor packages according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described more fully hereinafter with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. In the drawings, the thicknesses of layers and regions are exaggerated for clarity. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not. intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

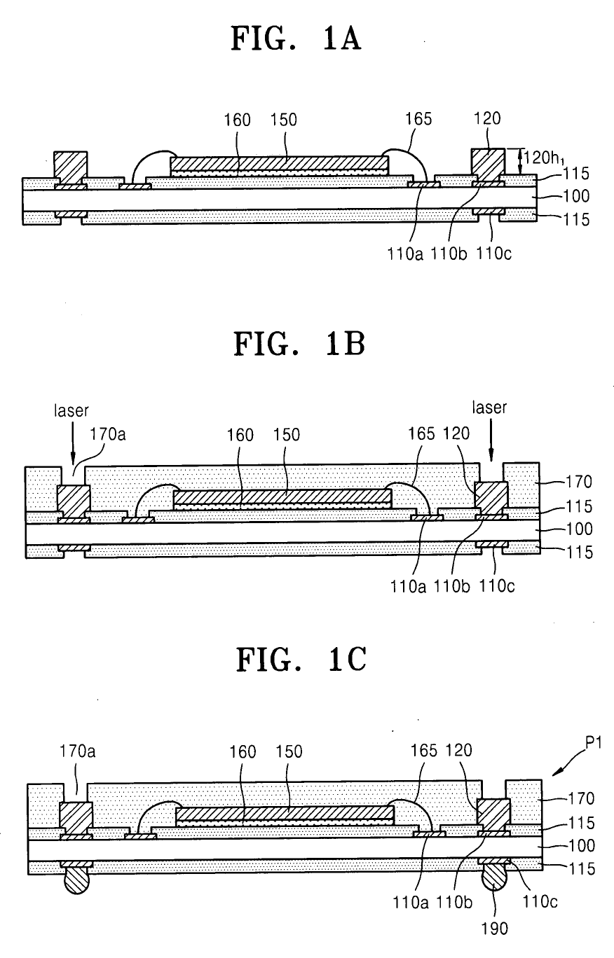

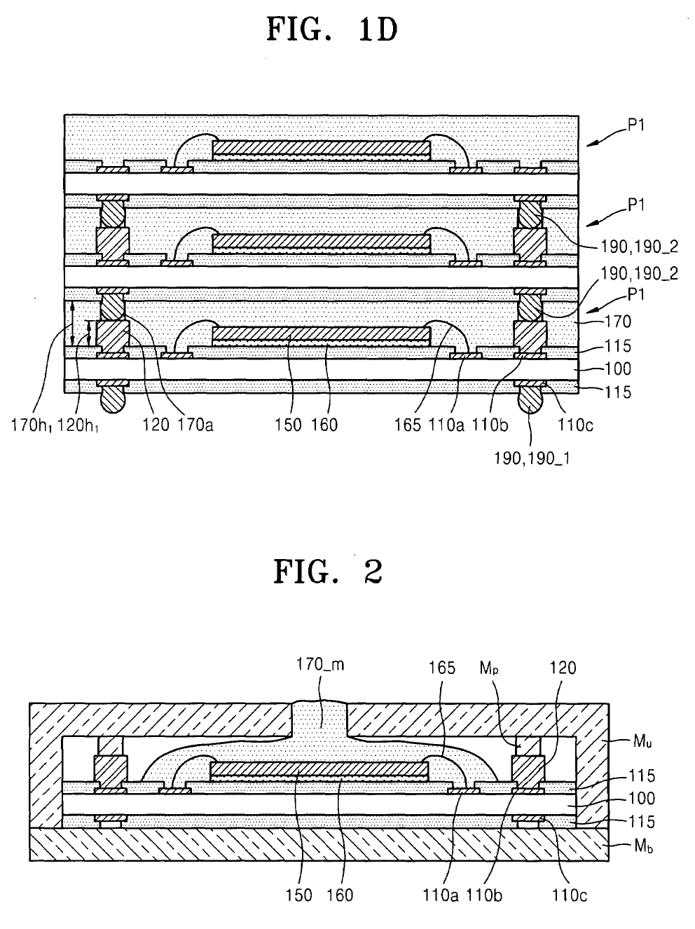

FIGS. 1A-1D are cross-sectional views illustrating a method of fabricating a stack type semiconductor package according to example embodiments. Referring to FIG. 1A, a substrate 100 may be provided. The substrate 100 may be a printed circuit board, a tape, a lead frame and/or a wafer, for example, a printed circuit board. A bump pad 110b and a wire bonding pad 110a may be disposed on the upper surface of the substrate 100, and a ball land 110c may be disposed on the lower surface of the substrate 100. A solder resist layer 115 may be disposed on the substrate 100, the bump pad 110b, the wire bonding pad 110a, and the ball land 110c. The solder resist layer 115 may have holes, and the bump pad 110b, the wire bonding pad 110a, and the ball land 110c may be partially exposed by each of the holes.

A bump 120 may be formed on the exposed bump pad 110b. The bump 120 may be formed of gold, silver, copper, nickel, aluminum, tin, lead, platinum, bismuth, indium, an alloy of one of these elements and/or an alloy composed of at least two of these elements. The bump 120 may be formed using electrolysis/electro plating, deposition, sputtering and/or screen printing. A height 120h₁ of the bump 120 may be determined in accordance with a height of a protecting layer to be explained later. A semiconductor chip 150 may be bonded to the upper surface of the substrate 100, using an insulating adhesive layer 160. A terminal pad (not shown) of the semiconductor chip 150 and the wire bonding pad 110a may be connected using a conductive wire 165.

Referring to FIG. 1B, a protecting layer 170 may be formed on the substrate 100 to cover the semiconductor chip 150, the conductive wire 165, and the bump 120. The protecting layer 170 may be formed using epoxy resin and/or another similar material. A via hole 170a exposing the bump 120 may be formed in the protecting layer 170. The via hole 170a may be formed using a laser. Referring to FIG. 1C, after placing a solder ball 190 on the exposed ball land 110c in the hole, thermal treatment may be applied to the components so as to electrically connect the solder ball 190 and the ball land 110c. Thus, a single unit package P1 may be completed.

Referring to FIG. 1D, a plurality of the unit packages P1 may be vertically stacked. An internal connection solder ball 190_2 disposed on a bottom surface of an upper unit package may be inserted into a via hole 170a of a lower unit package, so as to connect the internal connection solder ball 190_2 to the bump 120 of the lower unit package. The unit packages P1 may be electrically connected, thereby fabricating a stack type semiconductor package. Reliable connection between the stacked unit packages may be realized by inserting the internal connection solder ball 190_2 of the upper unit package into the via hole 170a formed in the protecting layer 170 of the lower unit package, and connecting the internal connection solder ball 190_2 to the exposed bump 120 in the via hole 170a.

Because a connection portion between the stacked unit packages, for example, a connection portion between the internal connection solder ball 190_2 and the bump 120, may be disposed inside the via hole 170a, even if physical impact is applied on the stack type semiconductor package, a possibility that the internal connection solder ball 190_2 and the bump 120 are disconnected at their connection portion may be relatively low. Further, because the bump 120 is formed, a height of the internal connection solder ball 190_2 may be reduced as compared to a structure without the bump 120. Thus, a relatively small-sized solder ball may be used, thereby providing relatively fine pitch between the solder balls and realizing a relatively densely integrated semiconductor device. The solder ball disposed on the lowest unit package may be an external connection solder ball 190_1, and the bump and the via hole may not be formed at the uppermost unit package. A height 120h₁ of the bump 120 may be determined in accordance with a height 170h₁ of the protecting layer 170.

FIG. 2 is a cross-sectional view illustrating a method of fabricating a single unit package according to example embodiments. The fabrication method in the example embodiment of FIG. 2 is similar to the method of fabricating the unit package explained in reference to FIGS. 1A-1C except for the portion explained below.

Referring to FIG. 2, the resultant structure fabricated by the method explained in reference to FIG. 1A, for example, the substrate 100 having the semiconductor chip 150 and the bump 120 may be disposed on a lower mold die Mb, and an upper mold die Mu may be disposed on the substrate 100. The upper mold die Mu may have a mold pin Mp protruding downward, and the mold pin Mp may be aligned with the bump 120. A molding material 170_m may fill a space between the substrate 100 and the upper mold die Mu.

The mold dies Mu and Mb may be removed, thereby forming the structure including the protecting layer 170 illustrated in FIG. 1B. The protecting layer 170 may have the via hole 170a formed by the mold pin Mp. When the via hole 170a is formed concurrently with the formation of the protecting layer 170, the number of fabrication processes may be reduced as compared to that of the example embodiment explained in reference to FIGS. 1A-1D.

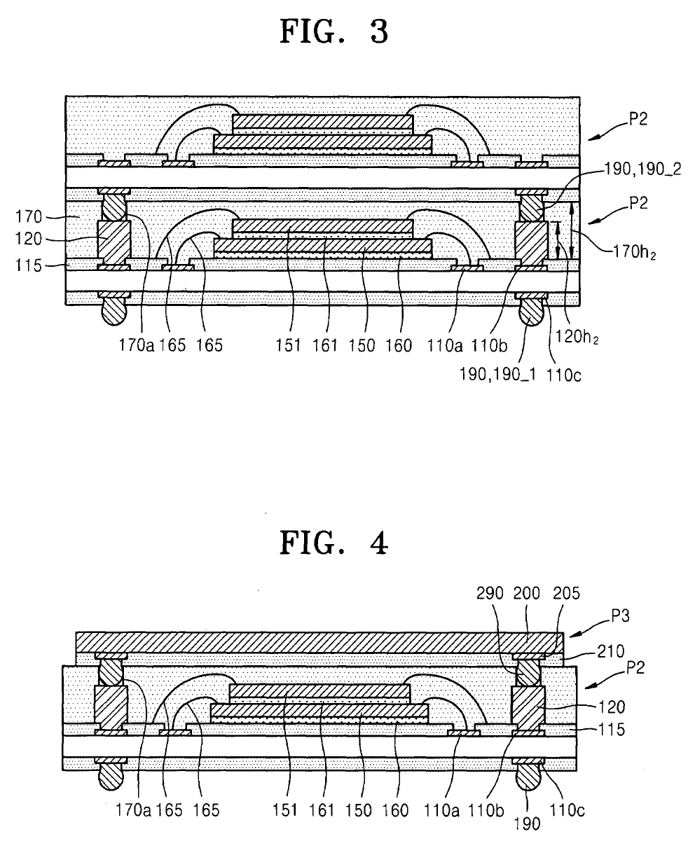

FIG. 3 is a cross-sectional view illustrating a stack type semiconductor package according to example embodiments. A fabrication method according to example embodiments may be similar to the method of fabricating the stack type semiconductor package explained in reference to FIGS. 1A-1D except for the portion explained below.

Referring to FIG. 3, a single unit package provided in the stack type package may be a multi chip package P2 unlike the unit package explained in reference to FIGS. 1A through 1D. For example, the unit package P2 may be structured such that a first semiconductor chip 150 may be mounted on a substrate 100 using an adhesive layer 160, and a second semiconductor chip 151 may be mounted on the first semiconductor chip using an adhesive layer 161. A terminal pad (not shown) of the first semiconductor chip 150 may be connected to a wire bonding pad 110a using a conductive wire 165, and a terminal pad (not shown) of the second semiconductor chip 151 may be connected to another wire bonding pad (not shown).

A protecting layer 170 may be formed to cover the first and second semiconductor chips 150 and 151, and the bump 120. In the example embodiment illustrated in FIG. 3, a height 170h₂ of the protecting layer 170 may be greater than the height 170h₁ of the protecting layer 170 of FIG. 1C. A height 120h₂ of the bump 120 may be greater than the height 120h₁ of the bump of FIG. 1C. As a result, the size of an internal connection solder ball 190_2 of the upper unit package connected to the bump 120 may not need to be increased. Thus, a pitch between the solder balls 190 may be reduced, thereby increasing an integration density.

FIG. 4 is a cross-sectional view illustrating a stack type semiconductor package according to example embodiments. Referring to FIG. 4, a lower unit package of the stack type semiconductor package may be the same as the multi chip package P2 illustrated in FIG. 3, and an upper unit package thereof may be a wafer level package P3. The description of the multi chip package P2 is made with reference to the description of FIG. 3. The wafer level package P3 may be structured such that a bond pad 205 may be formed on a lower surface of a semiconductor chip 200, a solder resist layer 210 having a hole partially exposing the bond pad 205 may be formed on the bond pad 205, and a solder ball 290 may be formed on the partially exposed bond pad 205. A solder ball, for example, an internal connection solder ball 290 of the upper unit package, for example, the wafer level package P3 may be inserted into a via hole 170a of the lower unit package P2, so as to connect the internal connection solder ball 290 to a bump 120 of the lower unit package P2. Thus, the stack type semiconductor package may be fabricated by electrically connecting the unit packages P2 and P3.

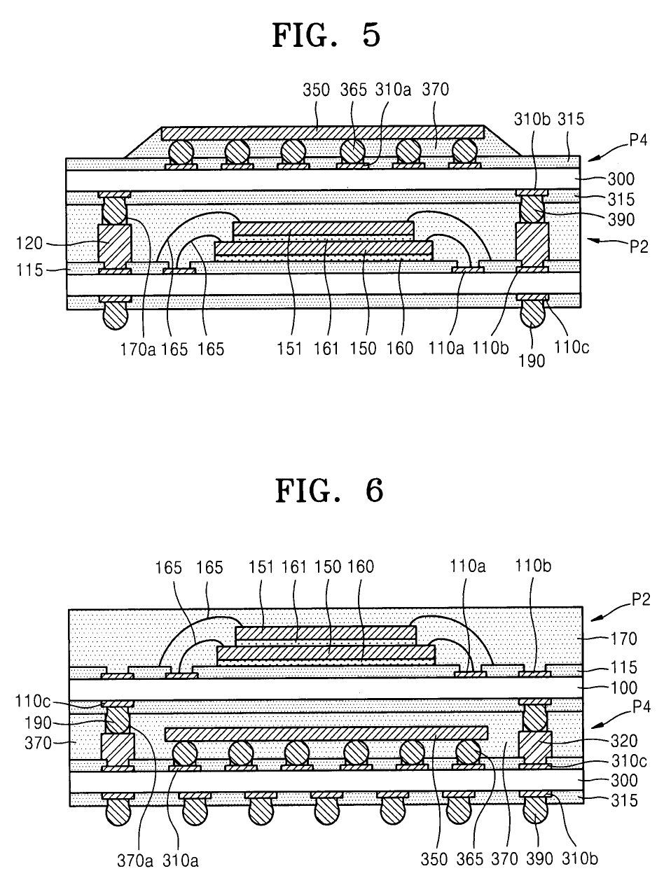

FIG. 5 is a cross-sectional view illustrating a stack type semiconductor package according to example embodiments. Referring to FIG. 5, a lower unit package of the stack type semiconductor package may be the same as the multi chip package P2 of FIG. 3, and an upper unit package thereof may be a flip chip package P4. The description of the multi chip package P2 is made with reference to the description of FIG. 3. The flip chip package P4 may be structured such that a conductive protrusion 365 may be formed on a bond pad (not shown) of a semiconductor chip 350, and the semiconductor chip 350 may be mounted on a circuit board 300 with the semiconductor chip 350 having the conductive protrusion 365 faced down. The circuit board 300 may include an upper ball land 310a disposed on its upper surface, a lower ball land 310b disposed on its lower surface, and a solder resist layer 315 having holes partially exposing the upper ball land 310a and the lower ball land 310b respectively. The conductive protrusion 365 may be connected to the upper ball land 310a. A protrusion protecting layer 370 may be formed around the conductive protrusions 365. A solder ball 390 may be disposed on the lower ball land 310b.

An internal connection solder ball 390 of the flip chip package P4 may be inserted into a via hole 170a of the lower unit package P2, so as to connect the internal connection solder ball 390 to a bump 120 of the lower unit package P2. Thus, the unit packages P4 and P2 may be electrically connected, thereby fabricating the stack type semiconductor package.

FIG. 6 is a cross-sectional view illustrating a stack type semiconductor package according to example embodiments. Referring to FIG. 6, a lower unit package of the stack type semiconductor package may be the same as the flip chip package P4 explained with reference to FIG. 5, and an upper unit package thereof may be a multi chip package P2 explained in reference to FIG. 3. The description of the multi chip package P2 is made with reference to the description of FIG. 3.

The flip chip package P4 may be structured such that a conductive protrusion 365 may be formed on a bond pad (not shown) of a semiconductor chip 350, and the semiconductor chip 350 may be mounted on a circuit board 300 with a side of the semiconductor chip 350 having the conductive protrusion 365 faced down. The circuit board 300 may include an upper ball land 310a disposed on its upper surface, a bump pad 310c, and a lower ball land 310b disposed on its lower surface, and may further include a solder resist layer 315 having holes partially exposing the upper ball land 310a, the bump pad 310c, and the lower ball land 310b. The conductive protrusion 365 may be connected to the upper ball land 310a. Further, a bump 320 may be formed on the bump pad 310c.

A protecting layer 370 may be formed to cover the semiconductor chip 350, the conductive protrusion 365, and the bump 320 on the circuit board 300. A via hole 370a exposing the bump 320 may be formed in the protecting layer 370. The via hole 370a may be formed using a laser, or alternatively, may be formed concurrently with the formation of the protecting layer 370, using the mold dies Mb and Mu as explained with reference to FIG. 2.

An internal connection solder ball 190 of the multi chip package P2 may be inserted into a via hole 370a of the lower unit package P4, so as to connect the internal connection solder ball 190 to a bump 320 of the lower unit package P4. Thus, the stack type semiconductor package may be fabricated by electrically connecting the unit packages P2 and P4 as above.

Therefore, as described above according to example embodiments, reliable connection between stacked unit packages may be provided by inserting the internal connection solder ball of the upper unit package into the via hole formed in the protecting layer of the lower unit package, for example, to the exposed bump in the via hole.

While example embodiments have been particularly shown and described with reference to example embodiments thereof, it will be understood by those of ordinary skill in the art that various changes in form and details may be made therein without departing from the spirit and scope of the following claims.

What is claimed is:

1. A stack type semiconductor package comprising:
a lower unit package which includes
a substrate;
a semiconductor chip on an upper surface of the substrate;
a bump on an upper surface of the substrate; and
a protecting layer covering the semiconductor chip, and having a via hole partially exposing the bump, and
an upper unit package on the protecting layer which includes
an internal connection solder ball on a lower surface thereof, the internal connection solder ball insertable into the via hole and connected to the bump of the lower unit package.

2. The stack type semiconductor package of claim 1, wherein the bump is on a bump pad on the substrate.

3. The stack type semiconductor package of claim 1, wherein the lower unit package further includes an external connection solder ball on a lower surface of the substrate.

4. The stack type semiconductor package of claim 1, wherein the semiconductor chip is electrically connected to the substrate by a conductive wire.

5. The stack type semiconductor package of claim 1, further comprising:
another semiconductor chip on the semiconductor chip, wherein the protecting layer covers both semiconductor chips.

6. The stack type semiconductor package of claim 1, wherein the semiconductor chip is a flip chip.

7. The stack type semiconductor package of claim 1, wherein the upper unit package is a wafer level package, a flip chip package, or a wire bonding ball grid array (BGA) package.

8. The stack type semiconductor package of claim 1, wherein the protecting layer includes epoxy resin.

9. A method of fabricating a stack type semiconductor package comprising:
forming a bump on an upper surface of a substrate;
providing a semiconductor chip on the upper surface of the substrate;
forming a protecting layer covering the semiconductor chip and the bump on the substrate, having a via hole partially exposing the bump, so as to form a lower semiconductor package;
providing an upper semiconductor package on the protecting layer, wherein providing the upper semiconductor package includes inserting an internal connection solder ball on a lower surface of the upper semiconductor package and into the via hole partially exposing the bump and connected to the bump of the lower semiconductor package.

10. The method of claim 9, wherein forming the protecting layer having the via hole comprises:
forming a protecting layer covering the semiconductor chip and the bump on the substrate, and
forming the via hole using a laser.

11. The method of claim 9, wherein forming the protecting layer having the via hole comprises:
providing the substrate having the bump and the semiconductor chip thereon on a lower mold die;
providing an upper mold die having a mold pin corresponding to the bump on the substrate; and
filling a space between the substrate and the upper mold die with a molding material.

12. The method of claim 9, wherein forming the bump includes forming the bump on a bump pad on the substrate.

13. The method of claim 9, further comprising:
providing an external connection solder ball on a lower surface of the substrate of the lower semiconductor package.

14. The method of claim 9, wherein providing the semiconductor chip includes electrically connecting the semiconductor chip to the substrate by a conductive wire.

15. The method of claim 9, further comprising:
providing another semiconductor chip on the semiconductor chip, wherein the protecting layer is formed to cover both semiconductor chips.

16. The method of claim 9, wherein the semiconductor chip is a flip chip.

17. The method of claim 9, wherein the upper unit package is a wafer level package, a flip chip package, or a wire bonding BGA package.

18. The method of claim 9, wherein the protecting layer includes epoxy resin.
